(19) United States
(12) Patent Application Publication
(10) Pub. No.: US 2025/0183012 A1
(43) Pub. Date: Jun. 5, 2025

(54) PLASMA PROCESSING APPARATUS AND ELECTROSTATIC CHUCK

(71) Applicant: Tokyo Electron Limited, Tokyo (JP)

(72) Inventors: Takashi ARAMAKI, Miyagi (JP); Kota SHIHOMMATSU, Miyagi (JP); Lifu LI, Miyagi (JP); Hiroshi TSUJIMOTO, Miyagi (JP)

(73) Assignee: Tokyo Electron Limited, Tokyo (JP)

(21) Appl. No.: 19/050,177

(22) Filed: Feb. 11, 2025

Related U.S. Application Data
(63) Continuation of application No. PCT/JP2023/028541, filed on Aug. 4, 2023.

(30) Foreign Application Priority Data
Aug. 16, 2022 (JP) 2022-129757

(51) Int. Cl. H01J 37/32

(52) U.S. Cl. CPC H01J 37/32715; H01J 37/32146; H01J 37/32174; H01J 37/32642; H01J 2237/334

(57) ABSTRACT

A plasma processing apparatus is provided with: a chamber; a substrate support disposed inside the chamber and including a conductive base, an electrostatic chuck having a substrate support surface and an edge ring support surface, an edge ring disposed on the edge ring support surface, a substrate bias electrode disposed below the substrate support surface, and an edge ring bias electrode disposed below the edge ring support surface; an upper electrode disposed above the substrate support; a radio frequency (RF) generator electrically connected to the conductive base and configured to generate an RF signal; a first voltage pulse generator electrically connected to the substrate bias electrode and configured to generate a sequence of first voltage pulses having a first voltage level; and a second voltage pulse generator electrically connected to the edge ring bias electrode and configured to generate a sequence of second voltage pulses having a second voltage level.

### CROSS-REFERENCE TO RELATED APPLICATIONS

This application is a bypass continuation application of International Application No. PCT/JP2023/028541 having an international filing date of Aug. 4, 2023, and designating the United States, the international application being based upon and claiming the benefit of priority from Japanese Patent Application No. 2022-129757, filed on Aug. 16, 2022, the entire contents of each are incorporated herein by reference.

### TECHNICAL FIELD

Exemplary embodiments of the present disclosure relate to a plasma processing apparatus and an electrostatic chuck.

### BACKGROUND

In a plasma processing apparatus, there is a technology disclosed in Patent Document 1 as a technology for alleviating the influence of a phase difference between an electric bias for a substrate and an electric bias for an edge ring on plasma processing.

### PRIOR ART DOCUMENT

### Patent Document

Patent Document 1: Japanese Laid-Open Patent Publication No. 2021-158134

### SUMMARY

According to one embodiment of the present disclosure, a plasma processing apparatus is provided to include: a chamber; a substrate support disposed inside the chamber and including a conductive base, an electrostatic chuck disposed on the conductive base and having a substrate support surface and an edge ring support surface, an edge ring disposed on the edge ring support surface to surround a substrate disposed on the substrate support surface, a substrate bias electrode disposed below the substrate support surface inside the electrostatic chuck, and an edge ring bias electrode disposed below the edge ring support surface inside the electrostatic chuck and extending to an edge portion of the substrate support surface in a plan view, wherein the edge ring bias electrode has an annular overlapping portion overlapping with the substrate bias electrode in the plan view, and the annular overlapping portion has a width of 9 mm to 11 mm in a diametric direction; an upper electrode disposed above the substrate support; a radio frequency (RF) generator electrically connected to the conductive base and configured to generate an RF signal; a first voltage pulse generator electrically connected to the substrate bias electrode and configured to generate a sequence of first voltage pulses having a first voltage level; and a second voltage pulse generator electrically connected to the edge ring bias electrode and configured to generate a sequence of second voltage pulses having a second voltage level.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is an explanatory diagram schematically showing an example of a plasma processing apparatus.

FIG. 2 is an explanatory diagram showing an example of a configuration of electrodes of a substrate support.

FIG. 3 is an explanatory diagram showing an example of a configuration of a bias electrode of the substrate support in a plan view.

FIG. 4 shows an example of waveforms of a first pulsed DC signal and a second pulsed DC signal.

FIG. 5 is an explanatory diagram showing a variation in a plasma sheath on an edge portion of a substrate.

FIG. 6 is a graph showing a relationship between a width of an annular overlapping portion and a variation in an ion incidence angle in a plane of a surface during an etching process.

FIG. 7A is a graph showing a relationship between a potential difference ΔV applied to a substrate bias electrode and an edge ring bias electrode and an etching rate in the plane of the surface when the width of the annular overlapping portion is 0 mm.

FIG. 7B is a graph showing a relationship between the potential difference ΔV applied to the substrate bias electrode and the edge ring bias electrode and the etching rate in the plane of the surface when the width of the annular overlapping portion is 10 mm.

FIG. 7C is a graph showing a relationship between the potential difference ΔV applied to the substrate bias electrode and the edge ring bias electrode and the etching rate in the plane of the surface when the width of the annular overlapping portion is 24.5 mm.

FIG. 8A is a graph showing a roundness of a film hole formed on the substrate when the width of the annular overlapping portion is 0 mm and the potential difference ΔV applied to the substrate bias electrode and the edge ring bias electrode is 0 V and 150 V.

FIG. 8B is a graph showing the roundness of the film hole formed on the substrate when the width of the annular overlapping portion is 10 mm and the potential difference ΔV applied to the substrate bias electrode and the edge ring bias electrode is 0 V and 150 V.

FIG. 8C is a graph showing the roundness of the film hole formed on the substrate when the width of the annular overlapping portion is 24.5 mm and the potential difference ΔV applied to the substrate bias electrode and the edge ring bias electrode is 0 V and 150 V.

FIG. 9 is a schematic diagram showing another example of a configuration in which a DC signal is supplied to the bias electrode in the substrate support.

### DETAILED DESCRIPTION

Hereinafter, various embodiments of the present disclosure will be described. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

According to one exemplary embodiment, there is provided a plasma processing apparatus including: a chamber; a substrate support disposed inside the chamber, wherein the substrate support includes a conductive base, an electrostatic chuck disposed on the conductive base and having a substrate support surface and an edge ring support surface, an edge ring disposed on the edge ring support surface to surround a substrate disposed on the substrate support surface, a substrate bias electrode disposed below the substrate support surface inside the electrostatic chuck, and an edge ring bias electrode disposed below the edge ring support surface inside the electrostatic chuck and extending to an edge portion of the substrate support surface in a plan view, wherein the edge ring bias electrode has an annular overlapping portion overlapping with the substrate bias electrode in the plan view, and the annular overlapping portion has a width of 9 mm to 11 mm in a diametric direction, an upper electrode disposed above the substrate support; a radio frequency (RF) generator electrically connected to the conductive base and configured to generate an RF signal; a first voltage pulse generator electrically connected to the substrate bias electrode and configured to generate a sequence of first voltage pulses having a first voltage level; and a second voltage pulse generator electrically connected to the edge ring bias electrode and configured to generate a sequence of second voltage pulses having a second voltage level.

In one exemplary embodiment, a vertical distance between the substrate bias electrode and the edge ring bias electrode is 9 mm to 11 mm.

In one exemplary embodiment, the substrate support further includes a substrate chuck electrode disposed between the substrate support surface and the substrate bias electrode.

In one exemplary embodiment, the substrate support further includes at least one edge ring chuck electrode disposed between the edge ring support surface and the edge ring bias electrode.

In one exemplary embodiment, the at least one edge ring chuck electrode includes an inner edge ring chuck electrode and an outer edge ring chuck electrode and is configured to adsorb the edge ring onto the edge ring support surface by a potential difference between the inner edge ring chuck electrode and the outer edge ring chuck electrode.

In one exemplary embodiment, the first voltage level has a negative polarity and the second voltage level has a negative polarity.

In one exemplary embodiment, the first voltage level is different from the second voltage level.

In one exemplary embodiment, an absolute value of the first voltage level is equal to or less than an absolute value of the second voltage level.

In one exemplary embodiment, the first voltage level ranges from 0 V to −15 kV.

In one exemplary embodiment, the second voltage level ranges from 0 V to −16.5 kV.

In one exemplary embodiment, the plasma processing apparatus further includes a first direct current (DC) power supply configured to generate a first DC signal having the first voltage level, and the first voltage pulse generator is configured to generate the sequence of first voltage pulses from the first DC signal.

In one exemplary embodiment, the plasma processing apparatus further includes a second DC power supply configured to generate a second DC signal having the second voltage level, and the second voltage pulse generator is configured to generate the sequence of second voltage pulses from the second DC signal.

In one exemplary embodiment, the plasma processing apparatus further includes a second DC power supply configured to generate a second DC signal having a third voltage level of a negative polarity, and the second voltage pulse generator is configured to generate the sequence of second voltage pulses from the first DC signal and the second DC signal.

In one exemplary embodiment, an absolute value of the third voltage level is smaller than an absolute value of the first voltage level.

In one exemplary embodiment, the third voltage level ranges from 0 V to −1.5 kV.

According to one exemplary embodiment, there is provided a plasma processing apparatus including: a plasma processing chamber; a substrate support disposed inside the plasma processing chamber, wherein the substrate support includes a conductive base, an electrostatic chuck disposed on the conductive base and having a substrate support surface and an edge ring support surface, an edge ring disposed on the edge ring support surface to surround a substrate disposed on the substrate support surface, a substrate bias electrode disposed below the substrate support surface inside the electrostatic chuck, and an edge ring bias electrode disposed below the edge ring support surface inside the electrostatic chuck and extending to an edge portion of the substrate support surface in a plan view, wherein the edge ring bias electrode has an annular overlapping portion overlapping with the substrate bias electrode in the plan view, and the annular overlapping portion has a width of 9 mm to 11 mm in a diametric direction; a first voltage pulse generator electrically connected to the substrate bias electrode and configured to generate a sequence of first voltage pulses having a first voltage level; and a second voltage pulse generator electrically connected to the edge ring bias electrode and configured to generate a sequence of second voltage pulses having a second voltage level.

According to one exemplary embodiment, there is provided an electrostatic chuck including: an electrostatic chuck main body having a substrate support surface and an edge ring support surface; a substrate bias electrode disposed below the substrate support surface inside the electrostatic chuck main body; an edge ring bias electrode disposed below the edge ring support surface inside the electrostatic chuck main body and extending to an edge portion of the substrate support surface in a plan view, wherein the edge ring bias electrode has an annular overlapping portion overlapping with the substrate bias electrode in the plan view, and the annular overlapping portion has a width of 9 mm to 11 mm in a diametric direction; a substrate chuck electrode disposed between the substrate support surface and the substrate bias electrode; and at least one edge ring chuck electrode disposed between the edge ring support surface and the edge ring bias electrode.

Hereinafter, various embodiments of the present disclosure will be described in detail with reference to the drawings. In the drawings, the same or similar elements will be given the same reference numerals, and redundant descriptions thereof will be omitted. Positional relationships such as upper, lower, left, and right will be described based on those shown in the drawings unless specified otherwise. Dimensional ratios in the drawings do not represent actual ratios, and the actual ratios are not limited to those shown in the drawings.

### <Example of Plasma Processing Apparatus 1>

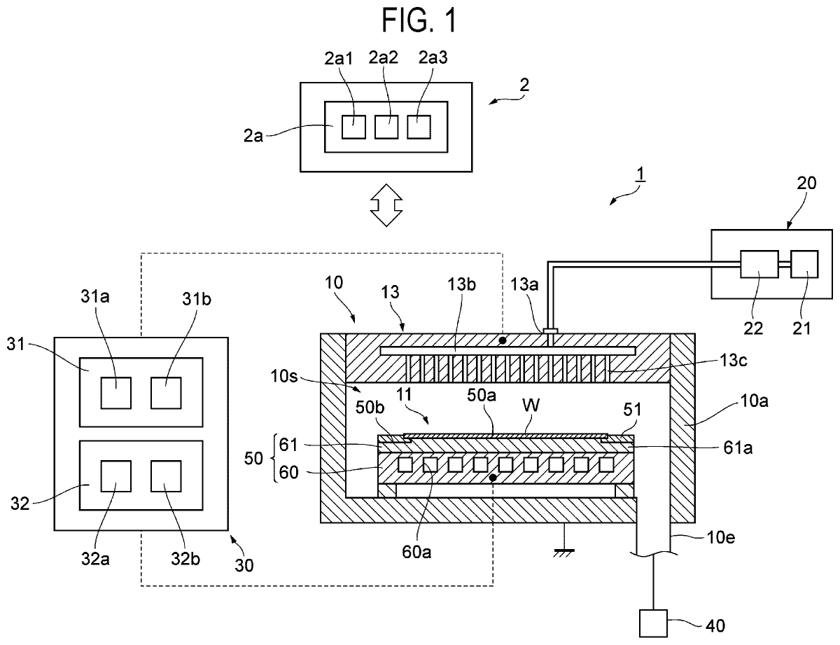

Hereinafter, an example of a configuration of a plasma processing system will be described. FIG. 1 is a diagram illustrating an example of a configuration of a capacitively coupled plasma processing apparatus. A plasma processing apparatus 1 according to an exemplary embodiment executes a plasma processing method of processing a substrate.

The plasma processing system includes the capacitively coupled plasma processing apparatus 1 and a controller 2. The capacitively coupled plasma processing apparatus 1 includes a plasma processing chamber (referred to simply as a “chamber”) 10, a gas supply 20, a power supply 30, and an exhaust system 40. The plasma processing apparatus 1 includes a substrate support (substrate supporting portion) 11 and a gas introduction unit. The gas introduction unit is configured to introduce at least one processing gas into the plasma processing chamber 10. The gas introduction unit includes a showerhead 13. The substrate support 11 is disposed in the plasma processing chamber 10. The showerhead 13 is disposed above the substrate support 11. In one embodiment, the showerhead 13 constitutes at least a part of a ceiling of the plasma processing chamber 10. The plasma processing chamber 10 has a plasma processing space (substrate processing space) 10s defined by the showerhead 13, a sidewall 10a of the plasma processing chamber 10, and the substrate support 11. The plasma processing chamber 10 includes at least one gas supply port for supplying at least one processing gas to the plasma processing space 10s therethrough, and at least one gas discharge port for discharging gas from the plasma processing space 10s therethrough. The plasma processing chamber 10 is grounded. The showerhead 13 and the substrate support 11 are electrically insulated from the plasma processing chamber 10.

The substrate support 11 includes a main body 50 and an edge ring 51. The main body 50 has a central region 50a for supporting a substrate W and an annular region 50b for supporting the edge ring 51. A wafer is an example of the substrate W. The annular region 50b of the main body 50 surrounds the central region 50a of the main body 50 in a plan view. The substrate W is disposed on the central region 50a of the main body 50, and the edge ring 51 is disposed on the annular region 50b of the main body 50 so as to surround the substrate W on the central region 50a of the main body 50. Therefore, the central region 50a is also referred to as a substrate support surface for supporting the substrate W, and the annular region 50b is also referred to as an edge ring support surface for supporting the edge ring 51. In one embodiment, the central region 50a may support the substrate W having a diameter of 300 mm. The central region 50a may have a diameter smaller than that of the substrate W.

In one embodiment, the main body 50 includes a base 60 and an electrostatic chuck 61. The base 60 includes a conductive member. The conductive member of the base 60 may function as a lower electrode. The electrostatic chuck 61 is disposed on the base 60. The electrostatic chuck 61 includes a ceramic member (electrostatic chuck main body) 61a and electrostatic electrodes (a substrate chuck electrode and an edge ring chuck electrode), which will be described later, disposed in the ceramic member 61a. The ceramic member 61a has the central region 50a. In one embodiment, the ceramic member 61a also has the annular region 50b. Other members surrounding the electrostatic chuck 61, such as an annular electrostatic chuck or an annular insulating member, may have the annular region 50b. In this case, the edge ring 51 may be disposed on the annular electrostatic chuck or the annular insulating member, or may be disposed on both the electrostatic chuck 61 and the annular insulating member. In addition, a radio frequency (RF) or direct current (DC) electrode may be disposed in the ceramic member 61a. In this case, the RF or DC electrode functions as the lower electrode. When a bias RF signal or a DC signal described later is supplied to the RF or DC electrode, the RF or DC electrode is also referred to as a bias electrode. Both the conductive member of the base 60 and the RF or DC electrode may function as two lower electrodes.

The edge ring 51 includes one or more annular members. In one embodiment, the one or more annular members include one or more edge rings and at least one cover ring. The edge ring is formed of a conductive material or an insulating material, and the cover ring is formed of an insulating material.

Further, the substrate support 11 may include a temperature control module configured to control at least one of the electrostatic chuck 61, the edge ring 51, or the substrate to a target temperature. The temperature control module may include a heater, a heat transfer medium, a flow passage 60a, or a combination thereof. A heat transfer fluid such as brine or gas flows through the flow passage 60a. In one embodiment, the flow passage 60a is formed in the base 60, and one or more heaters are disposed in the ceramic member 61a of the electrostatic chuck 61. The substrate support 11 may include a heat-transfer-gas supply configured to supply a heat transfer gas between a back surface of the substrate W and the central region 50a.

The substrate support 11 is provided with lifters (lifting pins) (not illustrated). In one embodiment, the lifters are disposed in a plurality of through-holes formed to penetrate the substrate support 11 in a vertical direction and move in the respective through-holes in the vertical direction by a driving device (not illustrated). In one embodiment, the substrate W is loaded into and unloaded from the plasma processing chamber 10 by a transfer arm (not illustrated). The lifters support the substrate W on the substrate support 11 and raise and lower the substrate W, thereby enabling the substrate W to be delivered between the transfer arm and the substrate support 11 and to be loaded onto the substrate support 11.

The showerhead 13 is configured to introduce at least one processing gas from the gas supply 20 into the plasma processing space 10s. The showerhead 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. The showerhead 13 includes an upper electrode. In addition to the showerhead 13, the gas introduction unit may include one or more side gas injectors (SGIs) installed in one or more openings formed in the sidewall 10a.

The gas supply 20 may include at least one gas source 21 and at least one flow controller 22. In one embodiment, the gas supply 20 is configured to supply at least one processing gas to the showerhead 13 from a corresponding one of the at least one gas source 21 via each corresponding flow controller 22. Each flow controller 22 may include, for example, a mass flow controller or a pressure-controlled flow controller. In addition, the gas supply 20 may include one or more flow modulation devices that modulate or pulse a flow of at least one processing gas.

The power supply 30 includes an RF power supply 31 coupled to the plasma processing chamber 10 via at least one impedance matching circuit. The RF power supply 31 is configured to supply at least one RF signal (RF power) such as the source RF signal and the bias RF signal to at least one lower electrode and/or at least one upper electrode. Thus, plasma is formed from the at least one processing gas supplied to the plasma processing space 10s. Therefore, the RF power supply 31 may function as at least a part of a plasma generator configured to generate a plasma from the one or more processing gases in the plasma processing chamber 10. Further, by supplying the bias RF signal to the at least one lower electrode, a bias potential is generated on the substrate W, thereby enabling ion components in the formed plasma to be drawn into the substrate W.

In one embodiment, the RF power supply 31 includes a first RF generator 31a and a second RF generator 31b. The first RF generator 31a is coupled to the at least one lower electrode and/or the at least one upper electrode via the at least one impedance matching circuit, and is configured to generate a source RF signal (source RF power) for plasma generation. In one embodiment, the source RF signal has a frequency in a range of 10 MHz to 150 MHz. In one embodiment, the first RF generator 31a may be configured to generate a plurality of source RF signals having different frequencies. The generated one or more source RF signals are supplied to the at least one lower electrode and/or the at least one upper electrode. In one embodiment, the first RF generator 31a is an example of an RF generator.

The second RF generator 31b is coupled to the at least one lower electrode via the at least one impedance matching circuit and is configured to generate the bias RF signal (bias RF power). A frequency of the bias RF signal may be the same as or different from the frequency of the source RF signal. In one embodiment, the bias RF signal has a frequency lower than that of the source RF signal. In one embodiment, the bias RF signal has a frequency in a range of 100 kHz to 60 MHz. In one embodiment, the second RF generator 31b may be configured to generate a plurality of bias RF signals having different frequencies. The generated one or more bias RF signals are supplied to the at least one lower electrode. In various embodiments, at least one of the source RF signal or the bias RF signal may be pulsed.

The power supply 30 may include a DC power supply 32 coupled to the plasma processing chamber 10. The DC power supply 32 includes a first DC generator 32a and a second DC generator 32b. In one embodiment, the first DC generator 32a is connected to the at least one lower electrode and is configured to generate a first DC signal. The generated first bias DC signal is applied to the at least one lower electrode. In one embodiment, the second DC generator 32b is connected to the at least one upper electrode and is configured to generate a second DC signal. The generated second DC signal is applied to the at least one upper electrode.

In various embodiments, at least one of the first DC signal or the second DC signal may be pulsed. In this case, a sequence of voltage pulses based on DC is applied to the at least one lower electrode and/or the at least one upper electrode. The voltage pulses may have pulse waveforms that are rectangular, trapezoidal, triangular, or combinations thereof. In one embodiment, a waveform generator for generating the sequence of voltage pulses from the DC signal is connected between the first DC generator 32a and the at least one lower electrode. Accordingly, the first DC generator 32a and the waveform generator constitute a voltage pulse generator. When the second DC generator 32b and the waveform generator constitute the voltage pulse generator, the voltage pulse generator is connected to the at least one upper electrode. The voltage pulses may have a positive polarity or a negative polarity. Further, the sequence of voltage pulses may include one or more positive voltage pulses or one or more negative voltage pulses in one cycle. The first DC generator 32a and the second DC generator 32b may be provided in addition to the RF power supply 31, and the first DC generator 32a may be provided instead of the second RF generator 31b. The first DC generator 32a may include a first DC power supply 111 and a second DC power supply 121, which will be described later.

The exhaust system 40 may be connected, for example, to a gas discharge port 10e provided at a bottom of the plasma processing chamber 10. The exhaust system 40 may include a pressure regulating valve and a vacuum pump. An internal pressure of the plasma processing space 10s is regulated by the pressure regulating valve. The vacuum pump may include a turbo-molecular pump, a dry pump, or a combination thereof.

The controller 2 processes computer-executable instructions that cause the plasma processing apparatus 1 to execute various processes described in the present disclosure. The controller 2 may be configured to control individual elements of the plasma processing apparatus 1 to execute various processes (plasma processing) described herein. The controller 2 is capable of executing the plasma processing by controlling the power supply 30, the exhaust system 40, the first voltage pulse generator 110 to be described later, the first DC power supply 111, the second voltage pulse generator 120, and the second DC power supply 121. In one embodiment, a part or the entirety of the controller 2 may be included in the plasma processing apparatus 1. The controller 2 may include, for example, a computer 2a. The computer 2a may include, for example, a processor (central processing unit (CPU)) 2a1, a storage 2a2, and a communication interface 2a3. The processor 2al may be configured to perform various control operations by reading a program from the storage 2a2 and executing the read program. This program may be stored in the storage 2a2 in advance or may be acquired from a medium when necessary. The acquired program is stored in the storage 2a2 and is read from the storage 2a2 and executed by the processor 2a1. The medium may be various non-transitory storage media readable by the computer 2a or may be a communication line connected to the communication interface 2a3. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

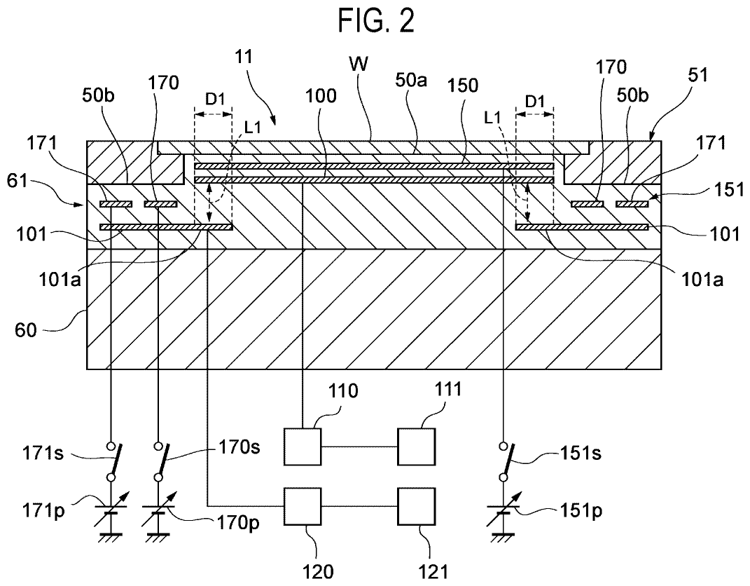

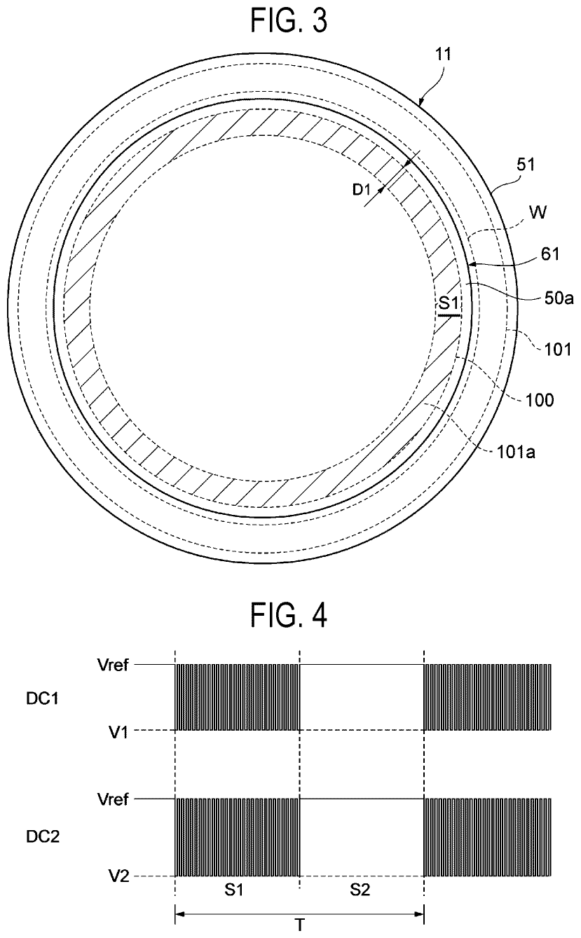

FIG. 2 is a longitudinal cross-sectional explanatory diagram showing an example of configurations of a bias electrode and a chuck electrode of the substrate support 11. FIG. 3 is an explanatory diagram showing an example of a configuration of the bias electrode of the substrate support in a plan view. As shown in FIG. 2, in one embodiment, the substrate support 11 includes a substrate bias electrode 100 and an edge ring bias electrode 101.

In one embodiment, the substrate bias electrode 100 is disposed below the central region 50a, which serves as a substrate support surface, in the electrostatic chuck 61. As shown in FIG. 3, in one embodiment, the substrate bias electrode 100 has a circular shape. The substrate bias electrode 100 is coaxially disposed with the central region 50a so that their centers coincide with each other in a plan view. In one embodiment, the substrate bias electrode 100 has a diameter smaller than that of the central region 50a. As shown in FIG. 2, in one embodiment, the substrate bias electrode 100 is electrically connected to a first voltage pulse generator 110 and a first DC power supply 111. The first DC power supply 111 may generate a first continuous DC signal having a first voltage level. The first voltage pulse generator 110 may generate a first pulsed DC signal from the first continuous DC signal generated by the first DC power supply 111 and apply the first pulsed DC signal to the substrate bias electrode 100. The first pulsed DC signal includes a sequence of first voltage pulses having the first voltage level. By applying the first pulsed DC signal to the substrate bias electrode 100, ion components in plasma formed on the substrate W, which is paced on the substrate support surface, may be drawn into the substrate W.

In one embodiment, the edge ring bias electrode 101 is disposed below the annular region 50b, which serves as an edge ring support surface, in the electrostatic chuck 61. As shown in FIG. 3, in one embodiment, the edge ring bias electrode 101 has an annular shape. In one embodiment, the edge ring bias electrode 101 is coaxially disposed with the central region 50a or the annular region 50b so that their centers coincide with each other in a plan view. As shown in FIGS. 2 and 3, the edge ring bias electrode 101 extends from the annular region 50b to an edge portion of the central region 50a in a plan view. Further, the edge ring bias electrode 101 has an annular overlapping portion 101a that partially overlaps the substrate bias electrode 100 in a plan view. The annular overlapping portion 101a has a width (overlapping width) D1 in a range of 9 mm to 11 mm in a diametric direction. As shown in FIG. 2, a vertical distance L1 between the edge ring bias electrode 101 and the substrate bias electrode 100 in the annular overlapping portion 101a is in a range of 9 mm to 11 mm.

In one embodiment, the substrate W has a diameter of 300 mm.

As shown in FIG. 2, in one embodiment, the edge ring bias electrode 101 is electrically connected to a second voltage pulse generator 120 and a second DC power supply 121. The second DC power supply 121 may generate a second continuous DC signal having a second voltage level. The second voltage pulse generator 120 may generate a second pulsed DC signal from the second continuous DC signal generated by the second DC power supply 121 and apply the second pulsed DC signal to the edge ring bias electrode 101. The second pulsed DC signal includes a sequence of second voltage pulses having the second voltage level. By applying the second pulsed DC signal to the edge ring bias electrode 101, ion components in plasma formed on an edge portion of the substrate W may be drawn into the edge portion of the substrate W.

FIG. 4 shows an example of waveforms of a first pulsed DC signal DC1 generated by the first voltage pulse generator 110 and a second pulsed DC signal DC2 generated by the second voltage pulse generator 120. The first pulsed DC signal DC1 has a sequence of first voltage pulses having a first voltage level V1 in a first state S1 within a repetition period T and a constant reference voltage level Vref in a second state S2 within the repetition period T. An absolute value of the reference voltage level Vref is smaller than an absolute value of the first voltage level V1. In one embodiment, the first voltage level V1 has a negative polarity. In one embodiment, the reference voltage level Vref has a zero voltage level. In one embodiment, the first voltage level V1 ranges from 0 V to −15 kV. In one embodiment, the sequence of first voltage pulses has a pulse frequency in a range of 100 kHz to 2 MHz. In one embodiment, the repetition period T has a repetition frequency in a range of 1 kHz to 50 kHz. The second pulsed DC signal DC2 has a sequence of second voltage pulses having a second voltage level V2 in the first state S1 and the constant reference voltage level Vref in the second state S2. An absolute value of the reference voltage level Vref is smaller than an absolute value of the second voltage level V2. In one embodiment, the first voltage level V2 has a negative polarity. In one embodiment, the absolute value of the second voltage level V2 is equal to the absolute value of the first voltage level V1. In one embodiment, the absolute value of the second voltage level V2 is greater than the absolute value of the first voltage level V1. In this case, a potential difference ΔV (V2−V1) is generated between the first voltage level V1 and the second voltage level V2. In one embodiment, the second voltage level V2 ranges from 0 V to −16.5 kV. In one embodiment, the sequence of second voltage pulses has a pulse frequency in a range of 100 kHz to 2 MHz.

As shown in FIG. 2, in one embodiment, the substrate support 11 may include a substrate chuck electrode 150 and at least one edge ring chuck electrode 151 as electrostatic electrodes.

In one embodiment, the substrate chuck electrode 150 may be disposed between the substrate support surface and the substrate bias electrode 100 in the electrostatic chuck 61. In one embodiment, the substrate chuck electrode 150 is connected to a DC power supply 151p via a switch 151s. When a DC voltage from the DC power supply 151p is applied to the substrate chuck electrode 150, an electrostatic attraction force (Coulomb force) is generated between the substrate chuck electrode 150 and the substrate W. The substrate W is attracted to the electrostatic chuck 61 by virtue of the electrostatic attraction force and is adsorbed to and held by the substrate support surface.

In one embodiment, the at least one edge ring chuck electrode 151 may be disposed between the edge ring support surface and the edge ring bias electrode 101 in the electrostatic chuck 61. In one embodiment, the at least one edge ring chuck electrode 151 includes an inner chuck electrode 170 and an outer chuck electrode 171. In one embodiment, the inner chuck electrode 170 is connected to a DC power supply 170p via a switch 170s. In one embodiment, the outer chuck electrode 171 is connected to a DC power supply 171p via a switch 171s. In one embodiment, a potential difference is generated between the inner chuck electrode 170 and the outer chuck electrode 171 of the at least one edge ring chuck electrode 151, and the edge ring 51 is adsorbed to and held by the edge ring support surface by this potential difference. In one embodiment, the polarity of a DC voltage applied to the inner chuck electrode 170 is different from the polarity of a DC voltage applied to the outer chuck electrode 171.

### <Example of Plasma Processing Method>

The plasma processing method includes an etching process for etching a film on the substrate W using plasma. In one embodiment, the plasma processing method is executed by the controller 2 of the plasma processing apparatus 1.

First, the substrate W is loaded into the plasma processing chamber 10 by a transfer arm, placed on the substrate support 11 by the lifters, and adsorbed to and held by the substrate support 11 as shown in FIG. 1.

Subsequently, the processing gas is supplied to the showerhead 13 by the gas supply 20 and is supplied to the plasma processing space 10s from the showerhead 13. The processing gas thus supplied includes gas that generates active species necessary for the etching process on the substrate W.

One or more RF signals are supplied from the RF power supply 31 to the upper electrode and/or the lower electrode. An internal atmosphere of the plasma processing space 10s may be exhausted via the gas exhaust port 10e to depressurize the interior of the plasma processing space 10s. Thus, plasma is generated on the substrate support 11 in the plasma processing space 10s, and the substrate W is subjected to the etching process.

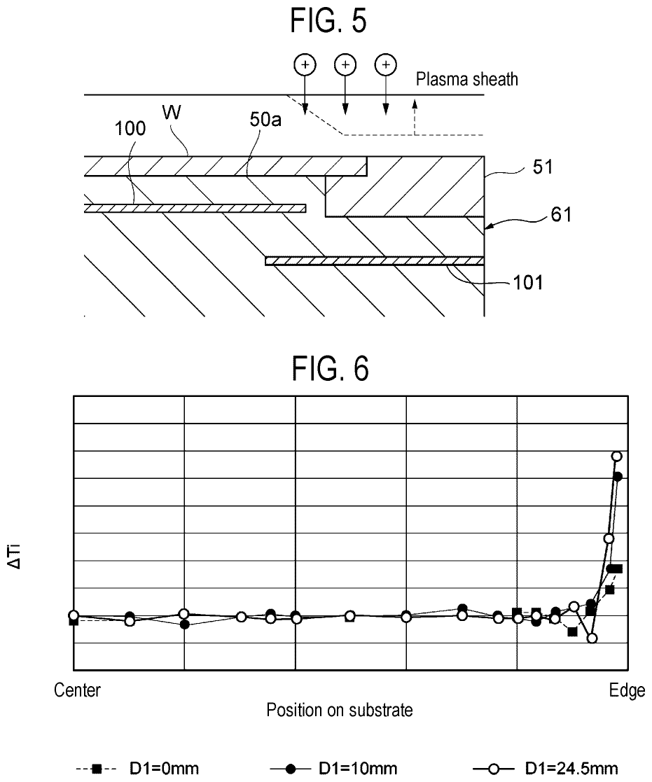

During plasma generation, the first pulsed DC signal DC1 is supplied to the substrate bias electrode 100 by the first voltage pulse generator 110 shown in FIG. 2, and the second pulsed DC signal DC2 is supplied to the edge ring bias electrode 101 by the second voltage pulse generator 120. Thus, a bias potential is generated on the substrate W and the edge ring 51 to draw ion components in the plasma over the substrate W into the substrate W. In this case, in one embodiment, the controller 2 controls the first voltage level V1 in the first pulsed DC signal DC1 supplied to the substrate bias electrode 100 and the second voltage level V2 in the second pulsed DC signal DC2 supplied to the edge ring bias electrode 101, thereby making a plasma sheath formed above the edge ring 51 approach in parallel (horizontally) with respect to the substrate W as shown in FIG. 5. Thus, an angle (ion incidence angle) of the ion components in the plasma at the edge portion of the substrate W becomes nearly perpendicular to the substrate W.

According to this exemplary embodiment, the substrate support 11 includes the substrate bias electrode 100 disposed below the substrate support surface in the electrostatic chuck 61 and the edge ring bias electrode 101 disposed below the edge ring support surface in the electrostatic chuck 61. The edge ring bias electrode 101 extends to the edge portion of the substrate support surface in a plan view and has the annular overlapping portion 101a that partially overlaps the substrate bias electrode 100 in a plan view. A width D1 of the annular overlapping portion 101a in a diametric direction is 9 mm to 11 mm. This enables the control of the ion incidence angle at the edge portion of the substrate W during the plasma process and suppresses a plasma processing result from varying upon controlling the ion incidence angle.

FIG. 6 shows results of verifying a relationship between the width D1 of the annular overlapping portion 101a and a variation in the ion incidence angle in the plane of the surface during the etching process. For verification, a substrate sample of a DRAM was used. The verification was conducted for cases in which the width D1 of the annular overlapping portion 101a was set to 0 mm, 10 mm, and 24.5 mm. The verification measured the ion incidence angle in the plane of the surface when the plasma process was performed by setting a potential difference ΔV between the first voltage level V1 applied to the substrate bias electrode 100 and the second voltage level V2 applied to the edge ring bias electrode 101 to 150 V (ion incidence angle under condition 1), and the ion incidence angle in the plane of the surface when the plasma process was performed by setting the potential difference ΔV between the first voltage level V1 and the second voltage level V2 to 0 V (there is no potential difference ΔV) (ion incidence angle under condition 2). The vertical axis in FIG. 6 indicates an ion incidence angle difference ΔTi obtained by subtracting the ion incidence angle under condition 2 from the ion incidence angle under condition 1, and the horizontal axis in FIG. 6 indicates a position in the plane of the surface. The left side of the horizontal axis in FIG. 6 represents the center of the substrate W, and the right side thereof represents the edge of the substrate W. The verification confirmed that, as the width D1 of the annular overlapping portion 101a increases, the variation in the ion incidence angle at the edge portion of the substrate W when the potential difference ΔV is applied increases (which is excellent in controllability of the ion incidence angle).

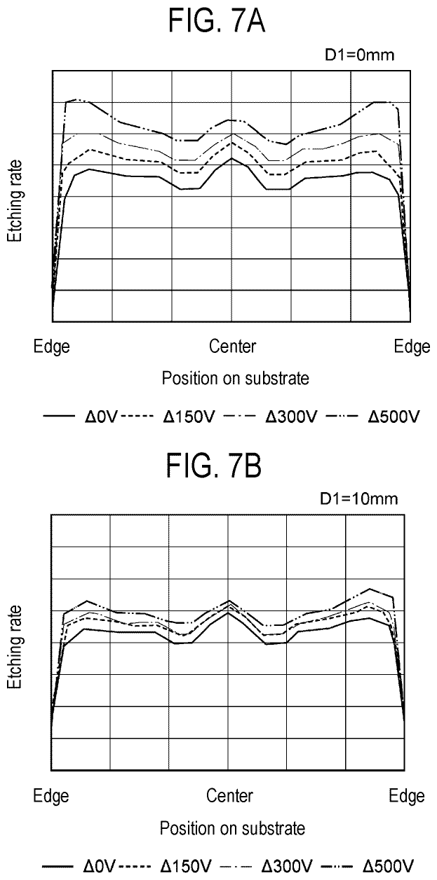

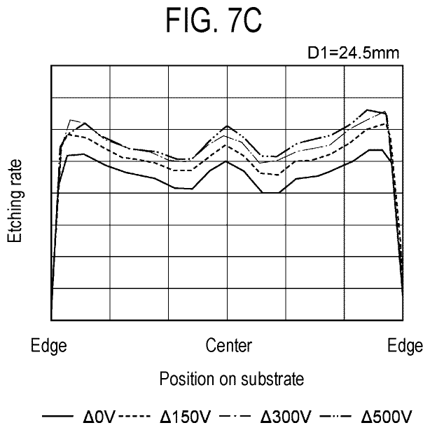

FIGS. 7A, 7B, and 7C show results of verifying a relationship between the potential difference ΔV applied to the substrate bias electrode 100 and the edge ring bias electrode 101 and an etching rate in the plane of the surface during the etching process for three widths D1 (0 mm, 10 mm, and 24.5 mm) of the three annular overlapping portions 101a. In each verification, the plasma process was performed on a substrate having a blanket film at a plurality of set potential differences ΔV (0 V, 150 V, 300 V, and 500 V), and an etching rate in the plane of the surface was measured. It can be confirmed from FIGS. 7A to 7C that when the width D1 of the annular overlapping portion 101a is set to 10 mm, the variation in the etching rate in the plane of the surface is small when the potential difference ΔV is changed.

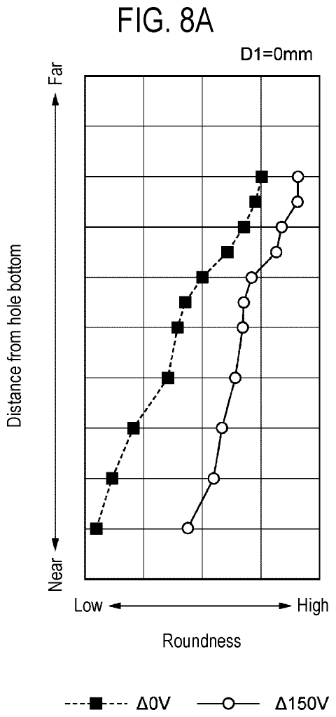

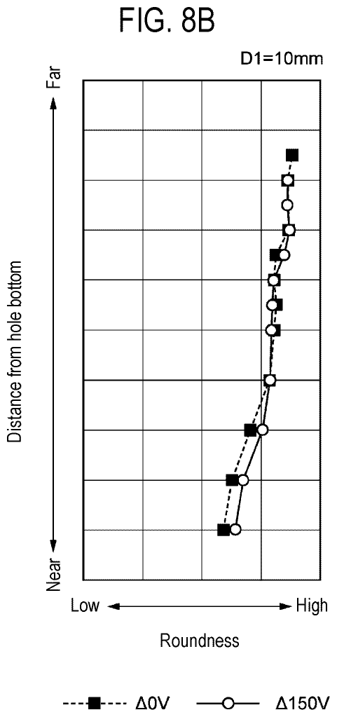

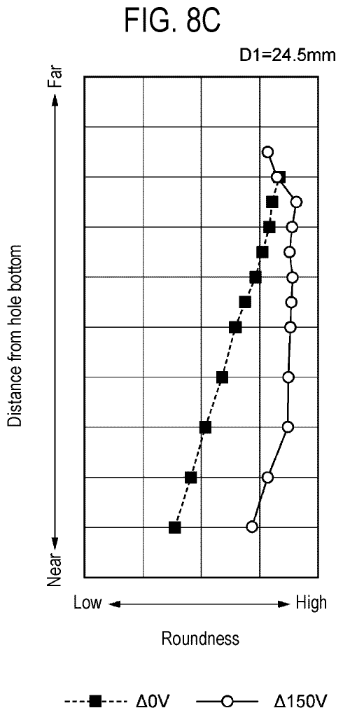

FIGS. 8A, 8B, and 8C show results of verifying a roundness of a film hole formed in an etched film of the substrate W when the potential difference ΔV applied to the substrate bias electrode 100 and the edge ring bias electrode 101 is set to 0 V and 150 V for three widths D1 (0 mm, 10 mm, and 24.5 mm) of the three annular overlapping portion 101a. In each verification, the roundness of the film hole in a depth direction at the edge portion of the substrate W was measured. The vertical axis in each of FIGS. 8A to 8C indicates a distance from the bottom of the film hole, and the horizontal axis thereof indicates the roundness of the film hole. It can be confirmed that when the width D1 of the annular overlapping portion 101a is set to 10 mm, the variation in the roundness of the film hole is small when the potential difference ΔV is applied.

From the above verification, by setting the width D1 of the annular overlapping portion 101a to an optimal range of 10 mm±1 mm (9 mm to 11 mm), the ion incidence angle at the edge portion of the substrate may be appropriately controlled using the potential difference ΔV applied to the substrate bias electrode 100 and the edge ring bias electrode 101. Further, by controlling the ion incidence angle using the potential difference ΔV, it is possible to suppress a variation in plasma processing results, such as the etching rate, the roundness of the film hole or the like. As a result, stable plasma processing results may be obtained even if the edge ring 51 is worn out and thus the ion incidence angle needs to be controlled by adjusting the potential difference ΔV.

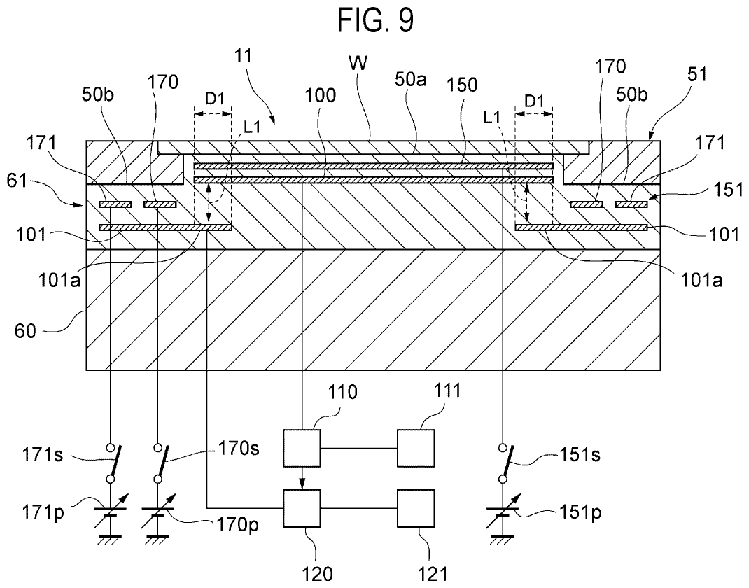

FIG. 9 is an explanatory diagram showing another example of a configuration in which the DC signal is applied to the bias electrode in the substrate support 11. In one embodiment, the second DC power supply 121 generates a third continuous DC signal having a third voltage level V3. In one embodiment, the third voltage level V3 has a negative polarity. In one embodiment, the second voltage pulse generator 120 is configured to generate the second pulsed DC signal from the first continuous DC signal and the third continuous DC signal. The second pulsed DC signal includes the sequence of second voltage pulses having the second voltage level. In one embodiment, an absolute value of the third voltage level V3 is smaller than the absolute value of the first voltage level V1. In one embodiment, the third voltage level V3 ranges from 0 V to −1.5 kV.

As an example, the case in which the third voltage level V3 is −1.5 kV and the first voltage level V1 is −10 kV will be described. In this case, the first voltage pulse generator 110 applies the first continuous DC signal having the first voltage level V1 of −10 kV to the second voltage pulse generator 120. The second voltage pulse generator 120 sums the third voltage level V3 of −1.5 kV and the first voltage level V1 of −10 kV to generate the second pulsed DC signal DC2 of −11.5 kV including the sequence of second voltage pulses. The second voltage pulse generator 120 applies the second pulsed DC signal DC2 to the edge ring bias electrode 101. The first voltage pulse generator 110 applies the first pulsed DC signal DC1 including the sequence of first voltage pulses having the first voltage level V1 of −10 kV to the substrate bias electrode 100. In this case, the potential difference ΔV applied to the substrate bias electrode 100 and the edge ring bias electrode 101 is 150 V. When the third voltage level V3 is 0 V, the first pulsed DC signal DC1 including the sequence of voltage pulses having the first voltage level V1 is applied to both the substrate bias electrode 100 and the edge ring bias electrode 101.

According to one exemplary embodiment of the present disclosure, it is possible to provide a technology capable of controlling an ion incidence angle at an edge portion of a substrate during plasma processing and suppressing a variation in a plasma processing result upon controlling the ion incidence angle.

In the above exemplary embodiments, the plasma processing apparatus may be modified in various forms without departing from the scope and idea of the present disclosure. For example, some constituent elements in an embodiment may be added to another embodiment within the scope of a creative capability of those skilled in the art. In addition, some constituent elements in an embodiment may be replaced with corresponding constituent elements in another embodiment.

The plasma processing apparatus may be a plasma processing apparatus using any plasma source such as inductively coupled plasma or microwave plasma, in addition to the capacitively coupled plasma processing apparatus. The plasma processing apparatus may not include an upper electrode and an RF generator. The embodiments of the present disclosure may further include the following aspects.

### (Supplementary Note 1)

A plasma processing apparatus includes:
a chamber;
a substrate support disposed inside the chamber, wherein the substrate support includes:
   a conductive base;
   an electrostatic chuck disposed on the conductive base and having a substrate support surface and an edge ring support surface;
   an edge ring disposed on the edge ring support surface to surround a substrate disposed on the substrate support surface;
   a substrate bias electrode disposed below the substrate support surface inside the electrostatic chuck; and
   an edge ring bias electrode disposed below the edge ring support surface inside the electrostatic chuck and extending to an edge portion of the substrate support surface in a plan view, wherein the edge ring bias electrode has an annular overlapping portion overlapping with the substrate bias electrode in the plan view, and the annular overlapping portion has a width of 9 mm to 11 mm in a diametric direction;
an upper electrode disposed above the substrate support;
a radio frequency (RF) generator electrically connected to the conductive base and configured to generate an RF signal;
a first voltage pulse generator electrically connected to the substrate bias electrode and configured to generate a sequence of first voltage pulses having a first voltage level; and
a second voltage pulse generator electrically connected to the edge ring bias electrode and configured to generate a sequence of second voltage pulses having a second voltage level.

### (Supplementary Note 2)

In the plasma processing apparatus of Supplementary Note 1 above, a vertical distance between the substrate bias electrode and the edge ring bias electrode is 9 mm to 11 mm.

### (Supplementary Note 3)

In the plasma processing apparatus of Supplementary Note 1 or 2 above, the substrate support further includes a substrate chuck electrode disposed between the substrate support surface and the substrate bias electrode.

### (Supplementary Note 4)

In the plasma processing apparatus of any one of Supplementary Notes 1 to 3 above, the substrate support further includes at least one edge ring chuck electrode disposed between the edge ring support surface and the edge ring bias electrode.

### (Supplementary Note 5)

In the plasma processing apparatus of Supplementary Note 4 above, the at least one edge ring chuck electrode includes an inner edge ring chuck electrode and an outer edge ring chuck electrode and is configured to adsorb the edge ring onto the edge ring support surface by a potential difference between the inner edge ring chuck electrode and the outer edge ring chuck electrode.

### (Supplementary Note 6)

In the plasma processing apparatus of any one of Supplementary Notes 1 to 5 above, the first voltage level has a negative polarity and the second voltage level has a negative polarity.

### (Supplementary Note 7)

In the plasma processing apparatus of any one of Supplementary Notes 1 to 6 above, the first voltage level is different from the second voltage level.

### (Supplementary Note 8)

In the plasma processing apparatus of any one of Supplementary Notes 1 to 6 above, an absolute value of the first voltage level is equal to or less than an absolute value of the second voltage level.

### (Supplementary Note 9)

In the plasma processing apparatus of any one of Supplementary Notes 1 to 8 above, the first voltage level ranges from 0 V to −15 kV.

### (Supplementary Note 10)

In the plasma processing apparatus of any one of Supplementary Notes 1 to 9 above, the second voltage level ranges from 0 V to −16.5 kV.

### (Supplementary Note 11)

The plasma processing apparatus of any one of Supplementary Notes 1 to 10 above further includes: a first direct current (DC) power supply configured to generate a first DC signal having the first voltage level,
wherein the first voltage pulse generator is configured to generate the sequence of first voltage pulses from the first DC signal.

### (Supplementary Note 12)

The plasma processing apparatus of Supplementary Note 11 above further includes: a second DC power supply configured to generate a second DC signal having the second voltage level,
wherein the second voltage pulse generator is configured to generate the sequence of second voltage pulses from the second DC signal.

### (Supplementary Note 13)

The plasma processing apparatus of Supplementary Note 11 above further includes: a second DC power supply configured to generate a second DC signal having a third voltage level of a negative polarity,
wherein the second voltage pulse generator is configured to generate the sequence of second voltage pulses from the first DC signal and the second DC signal.

### (Supplementary Note 14)

The plasma processing apparatus of Supplementary Note 13 above, wherein an absolute value of the third voltage level is smaller than an absolute value of the first voltage level.

### (Supplementary Note 15)

The plasma processing apparatus of Supplementary Note 13 or 14 above, wherein the third voltage level ranges from 0 V to −1.5 kV.

### (Supplementary Note 16)

A plasma processing apparatus includes:
a plasma processing chamber;
a substrate support disposed inside the plasma processing chamber, wherein the substrate support includes:
   a conductive base;
   an electrostatic chuck disposed on the conductive base and having a substrate support surface and an edge ring support surface;
   an edge ring disposed on the edge ring support surface to surround a substrate disposed on the substrate support surface;
   a substrate bias electrode disposed below the substrate support surface inside the electrostatic chuck; and
   an edge ring bias electrode disposed below the edge ring support surface inside the electrostatic chuck and extending to an edge portion of the substrate support surface in a plan view, wherein the edge ring bias electrode has an annular overlapping portion overlapping with the substrate bias electrode in the plan view, and the annular overlapping portion has a width of 9 mm to 11 mm in a diametric direction;
a first voltage pulse generator electrically connected to the substrate bias electrode and configured to generate a sequence of first voltage pulses having a first voltage level; and
a second voltage pulse generator electrically connected to the edge ring bias electrode and configured to generate a sequence of second voltage pulses having a second voltage level.

### (Supplementary Note 17)

An electrostatic chuck, comprising:
an electrostatic chuck main body having a substrate support surface and an edge ring support surface;
a substrate bias electrode disposed below the substrate support surface inside the electrostatic chuck main body;
an edge ring bias electrode disposed below the edge ring support surface inside the electrostatic chuck main body and extending to an edge portion of the substrate support surface in a plan view, wherein the edge ring bias electrode has an annular overlapping portion overlapping with the substrate bias electrode in the plan view, and the annular overlapping portion has a width of 9 mm to 11 mm in a diametric direction;
a substrate chuck electrode disposed between the substrate support surface and the substrate bias electrode; and
at least one edge ring chuck electrode disposed between the edge ring support surface and the edge ring bias electrode.

What is claimed is:

1. A plasma processing apparatus, comprising:
a chamber;
a substrate support disposed in the chamber, wherein the substrate support includes:
a conductive base;
an electrostatic chuck disposed on the conductive base and having a substrate support surface and an edge ring support surface;
an edge ring disposed on the edge ring support surface to surround a substrate disposed on the substrate support surface;
a substrate bias electrode disposed below the substrate support surface in the electrostatic chuck; and
an edge ring bias electrode disposed below the edge ring support surface in the electrostatic chuck and extending to an edge portion of the substrate support surface in a plan view, wherein the edge ring bias electrode has an annular overlapping portion overlapping with the substrate bias electrode in the plan view, and the annular overlapping portion has a width in a range of 9 mm to 11 mm in a diametric direction;
an upper electrode disposed above the substrate support;
a radio frequency (RF) generator electrically connected to the conductive base and configured to generate an RF signal;
a first voltage pulse generator electrically connected to the substrate bias electrode and configured to generate a sequence of first voltage pulses having a first voltage level; and
a second voltage pulse generator electrically connected to the edge ring bias electrode and configured to generate a sequence of second voltage pulses having a second voltage level.

2. The plasma processing apparatus of claim 1, wherein a vertical distance between the substrate bias electrode and the edge ring bias electrode is in a range of 9 mm to 11 mm.

3. The plasma processing apparatus of claim 1, wherein the substrate support further includes a substrate chuck electrode disposed between the substrate support surface and the substrate bias electrode.

4. The plasma processing apparatus of claim 3, wherein the substrate support further includes at least one edge ring chuck electrode disposed between the edge ring support surface and the edge ring bias electrode.

5. The plasma processing apparatus of claim 4, wherein the at least one edge ring chuck electrode includes an inner edge ring chuck electrode and an outer edge ring chuck electrode and is configured to adsorb the edge ring onto the edge ring support surface by a potential difference between the inner edge ring chuck electrode and the outer edge ring chuck electrode.

6. The plasma processing apparatus of claim 1, wherein the first voltage level has a negative polarity and the second voltage level has a negative polarity.

7. The plasma processing apparatus of claim 6, wherein the first voltage level is different from the second voltage level.

8. The plasma processing apparatus of claim 6, wherein an absolute value of the first voltage level is equal to or less than an absolute value of the second voltage level.

9. The plasma processing apparatus of claim 8, wherein the first voltage level is in a range of 0 V to −15 kV.

10. The plasma processing apparatus of claim 9, wherein the second voltage level is in a range of 0 V to −16.5 kV.

11. The plasma processing apparatus of claim 1, further comprising: a first direct current (DC) power supply configured to generate a first DC signal having the first voltage level,
wherein the first voltage pulse generator is configured to generate the sequence of first voltage pulses from the first DC signal.

12. The plasma processing apparatus of claim 11, further comprising: a second DC power supply configured to generate a second DC signal having the second voltage level,
wherein the second voltage pulse generator is configured to generate the sequence of second voltage pulses from the second DC signal.

13. The plasma processing apparatus of claim 11, further comprising: a second DC power supply configured to generate a second DC signal having a third voltage level of a negative polarity,
wherein the second voltage pulse generator is configured to generate the sequence of second voltage pulses from the first DC signal and the second DC signal.

14. The plasma processing apparatus of claim 13, wherein an absolute value of the third voltage level is less than an absolute value of the first voltage level.

15. The plasma processing apparatus of claim 14, wherein the third voltage level is in a range of 0 V to −1.5 kV.

16. A plasma processing apparatus, comprising:
a plasma processing chamber;
a substrate support disposed in the plasma processing chamber, wherein the substrate support includes:
a conductive base;
an electrostatic chuck disposed on the conductive base and having a substrate support surface and an edge ring support surface;
an edge ring disposed on the edge ring support surface to surround a substrate disposed on the substrate support surface;
a substrate bias electrode disposed below the substrate support surface in the electrostatic chuck; and
an edge ring bias electrode disposed below the edge ring support surface in the electrostatic chuck and extending to an edge portion of the substrate support surface in a plan view, wherein the edge ring bias electrode has an annular overlapping portion overlapping with the substrate bias electrode in the plan view, and the annular overlapping portion has a width in a range of 9 mm to 11 mm in a diametric direction;
a first voltage pulse generator electrically connected to the substrate bias electrode and configured to generate a sequence of first voltage pulses having a first voltage level; and
a second voltage pulse generator electrically connected to the edge ring bias electrode and configured to generate a sequence of second voltage pulses having a second voltage level.

17. An electrostatic chuck, comprising:
an electrostatic chuck main body having a substrate support surface and an edge ring support surface;
a substrate bias electrode disposed below the substrate support surface in the electrostatic chuck main body;
an edge ring bias electrode disposed below the edge ring support surface in the electrostatic chuck main body and extending to an edge portion of the substrate support surface in a plan view, wherein the edge ring bias electrode has an annular overlapping portion overlapping with the substrate bias electrode in the plan view, and the annular overlapping portion has a width in a range of 9 mm to 11 mm in a diametric direction;
a substrate chuck electrode disposed between the substrate support surface and the substrate bias electrode; and
at least one edge ring chuck electrode disposed between the edge ring support surface and the edge ring bias electrode.
